(19) United States
(12) Patent Application Publication
(10) Pub. No.: US 2026/0293087 A1
(43) Pub. Date: Sep. 24, 2026

(54) CAPACITOR STRUCTURE AND MANUFACTURING METHOD THEREOF

(71) Applicant: NANYA TECHNOLOGY CORPORATION, New Taipei City (TW)

(72) Inventor: Wen-Chieh Wang, New Taipei City (TW)

(73) Assignee: NANYA TECHNOLOGY CORPORATION, New Taipei City (TW)

(21) Appl. No.: 19/087,622

(22) Filed: Mar. 24, 2025

(51) Int. Cl. H10B 12/00; H10D 1/68

(52) U.S. Cl. CPC H10B 12/033; H10B 12/30; H10D 1/716

(57) ABSTRACT

A capacitor structure and a manufacturing method thereof are provided. The manufacturing method of the capacitor structure of the present invention includes the following steps. A bottom electrode is formed. An oxide layer is deposited on the bottom electrode. During the depositing of the oxide layer, a portion of the bottom electrode is oxidized to form an oxide film. The oxide layer and the oxide film of the bottom electrode are removed. An insulation layer is formed on the remaining bottom electrode. A top electrode is formed on the insulation layer.

### BACKGROUND

### Technical Field

The present invention relates to a semiconductor device, and in particular to a capacitor structure in the semiconductor device and a manufacturing method thereof.

### Description of Related Art

A semiconductor device, such as a dynamic random-access memory (DRAM), requires high capacitance for data saving and reading. The profile of the capacitor becomes larger, a larger surface area can be obtained and thus a higher capacitance is achieved. However, when the profile of the capacitor becomes larger, the distance between the adjacent capacitors becomes smaller, and a short circuit problem may be occurred between two adjacent capacitors.

### SUMMARY

The present invention provides a capacitor structure and a manufacturing method thereof, which could reduce the possibility of the short circuit problem between adjacent capacitors in a simple way.

The manufacturing method of the capacitor structure of the present invention includes the following steps. A bottom electrode is formed. An oxide layer is deposited on the bottom electrode. During the depositing of the oxide layer, a portion of the bottom electrode is oxidized to form an oxide film. The oxide layer and the oxide film of the bottom electrode are removed. An insulation layer is formed on the remaining bottom electrode. A top electrode is formed on the insulation layer.

In an embodiment of the manufacturing method of the capacitor structure of the present invention, an average thickness of the remaining bottom electrode after the oxide layer and the oxide film are removed is less than an average thickness of the bottom electrode before the oxide layer is deposited.

In an embodiment of the manufacturing method of the capacitor structure of the present invention, forming the bottom electrode includes the following steps. A stack structure is formed over a substrate, wherein the stack structure comprises a first support layer, a first sacrificial layer, a second support layer, a second sacrificial layer and a third support layer stacked sequentially over the substrate. An opening penetrating through the stack structure is formed. The bottom electrode is deposited in the opening.

In an embodiment of the manufacturing method of the capacitor structure of the present invention, the manufacturing method further includes the following steps. The first sacrificial layer and the second sacrificial layer are removed to expose an inner surface and an outer surface of the bottom electrode. The oxide layer is deposited on the inner surface and the outer surface of the bottom electrode, wherein during the depositing of the oxide layer, the inner surface and the outer surface of the bottom electrode is oxidized to form the oxide film.

In an embodiment of the manufacturing method of the capacitor structure of the present invention, the manufacturing method further includes the following steps. The second sacrificial layer is removed to expose an upper portion of the bottom electrode. The oxide layer is deposited on a sidewall of the upper portion of the bottom electrode. The first sacrificial layer, the oxide layer and the oxide film of the bottom electrode are removed.

In an embodiment of the manufacturing method of the capacitor structure of the present invention, during the depositing of the oxide layer, a lower portion of the bottom electrode layer is not oxidized.

In an embodiment of the manufacturing method of the capacitor structure of the present invention, the oxide layer includes silicon oxide and the oxide film of the bottom electrode includes titanium oxide.

The capacitor structure of the present invention includes a bottom electrode, an insulation layer, a top electrode and support layers. The insulation layer is disposed on the bottom electrode. The top electrode is disposed on the insulation layer. The support layers surrounds the bottom electrode. A width of a portion of the bottom electrode in direct contact with the support layers is greater than a width of a portion of the bottom electrode adjacent to the support layers but not in contact with the support layers.

In an embodiment of the capacitor structure of the present invention, the support layers comprises a first support layer surrounding the bottom end of the bottom electrode, a third support layer surrounding a top end of the bottom electrode and a second support layer located between the first support layer and the third support layer and surrounding a portion of the bottom electrode between the top end and the bottom end.

In an embodiment of the capacitor structure of the present invention, a first width of a portion of the bottom electrode in direct contact with the second support layer is greater than a second width of a portion of the bottom electrode adjacent to an upper surface of the second support layer but not in contact with the second support layer, and the first width of a portion of the bottom electrode in direct contact with the second support layer is greater than a third width of a portion of the bottom electrode adjacent to a lower surface of the second support layer but not in contact with the second support layer.

In an embodiment of the capacitor structure of the present invention, a width of a portion of the bottom electrode in direct contact with the first support layer is greater than a width of a portion of the bottom electrode adjacent to an upper surface of the first support layer but not in contact with the first support layer.

In an embodiment of the capacitor structure of the present invention, a neck of the bottom electrode is located adjacent to a bottom surface of the third support layer.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A-1H are schematic cross-sectional views of the manufacturing method of a capacitor structure according to an embodiment of the present invention.

FIGS. 2A-2E are schematic cross-sectional views of the manufacturing method of a capacitor structure according to another embodiment of the present invention.

FIGS. 3A-3D are schematic cross-sectional views of the manufacturing method of a capacitor structure according to another embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

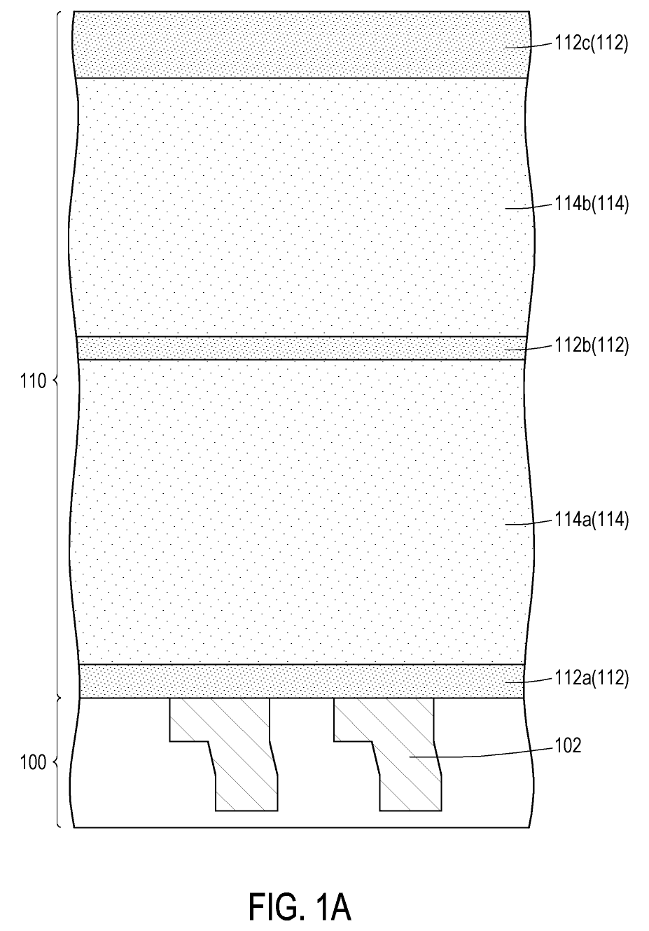

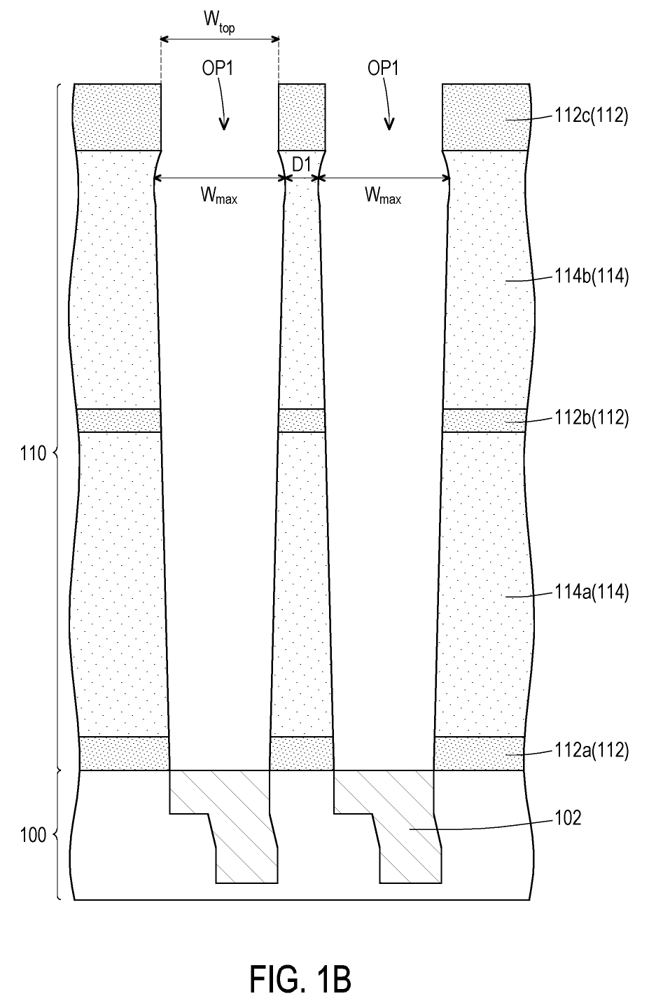

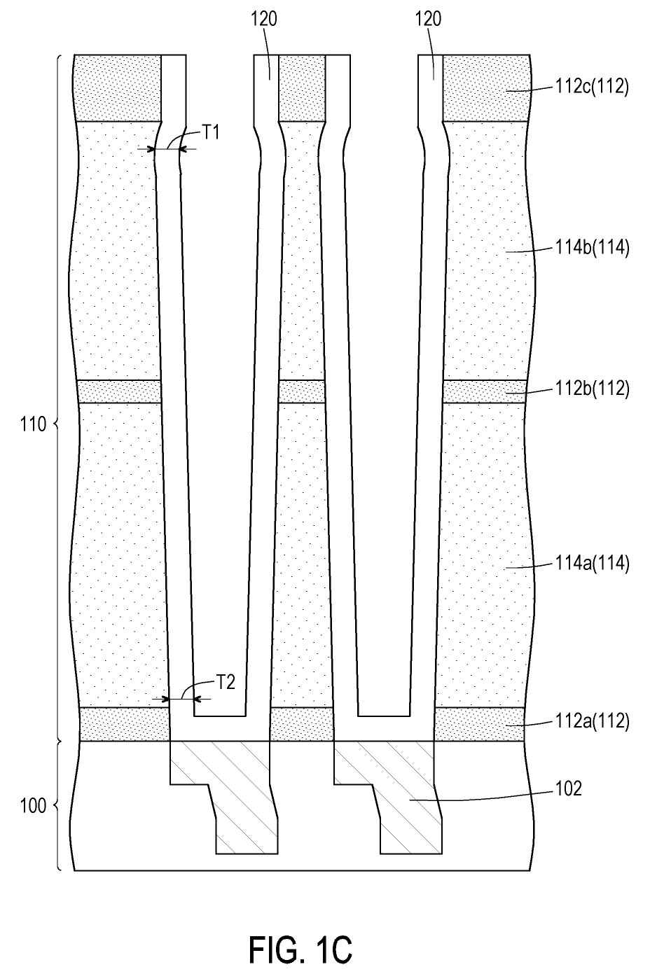

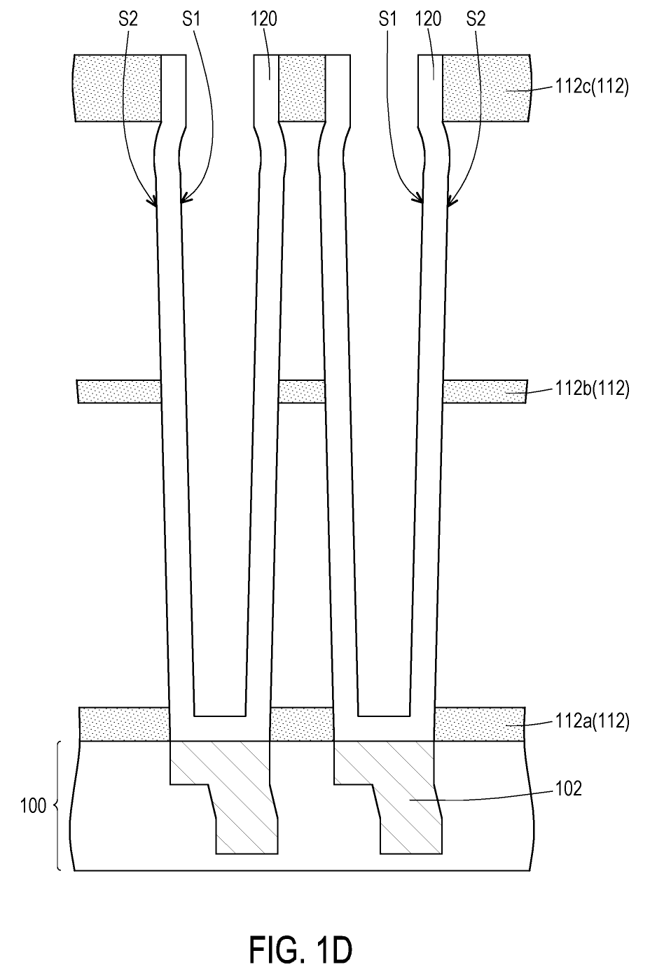

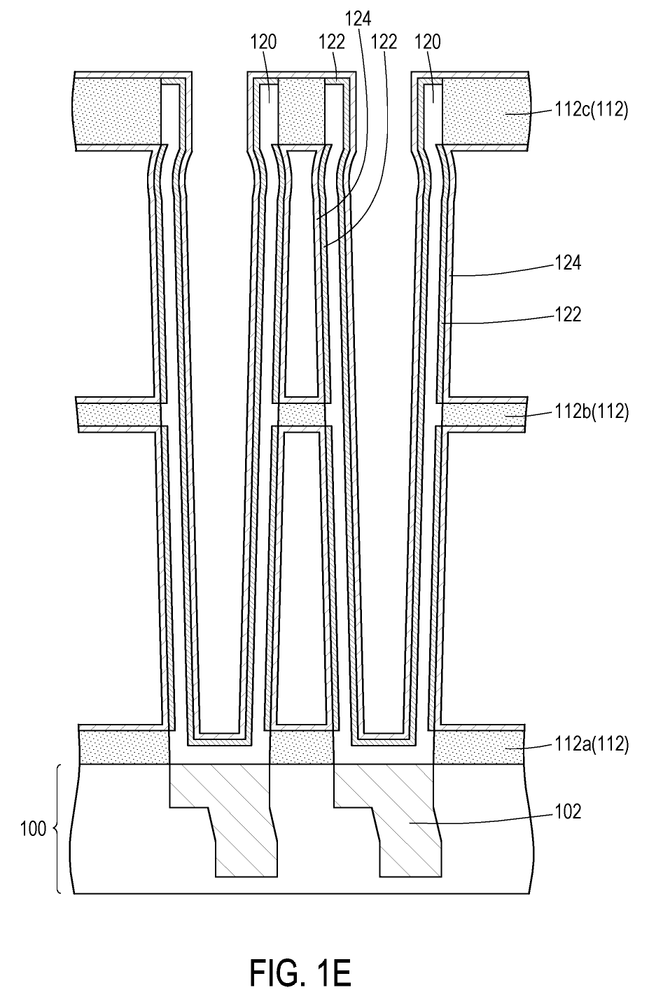

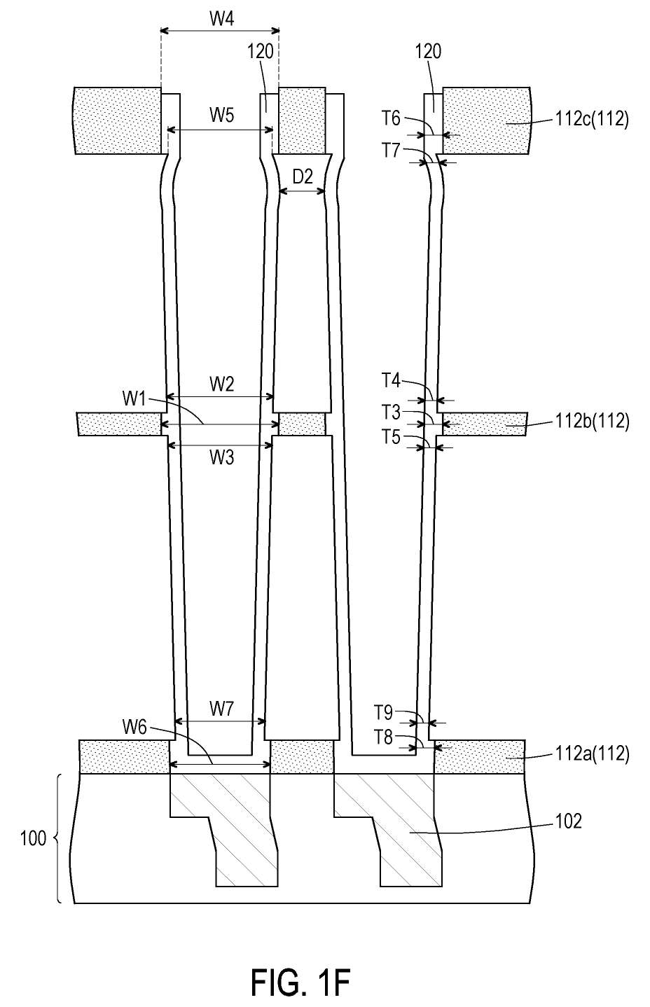

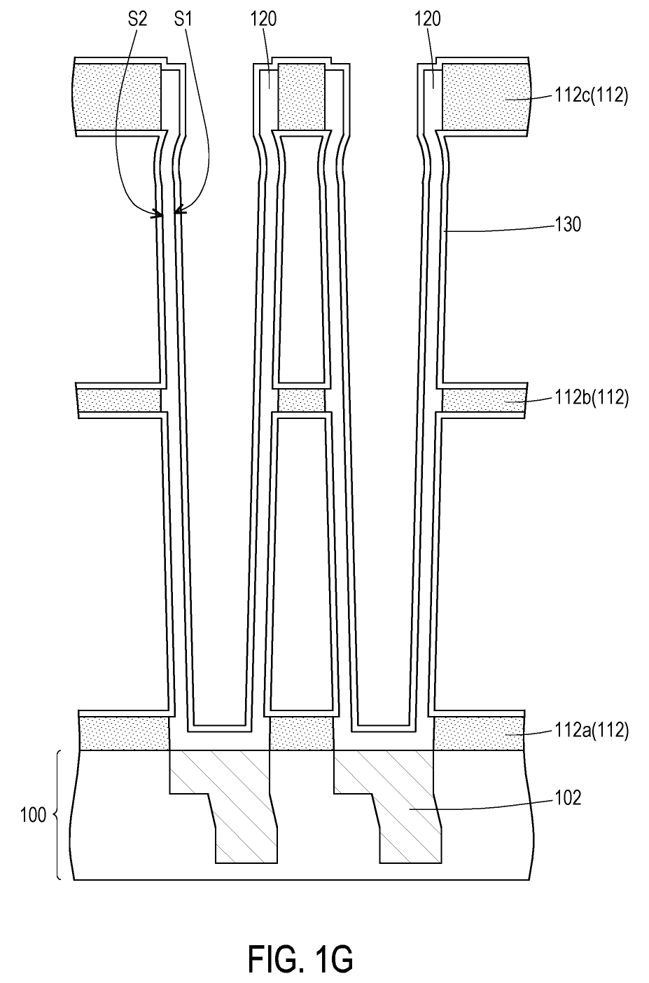

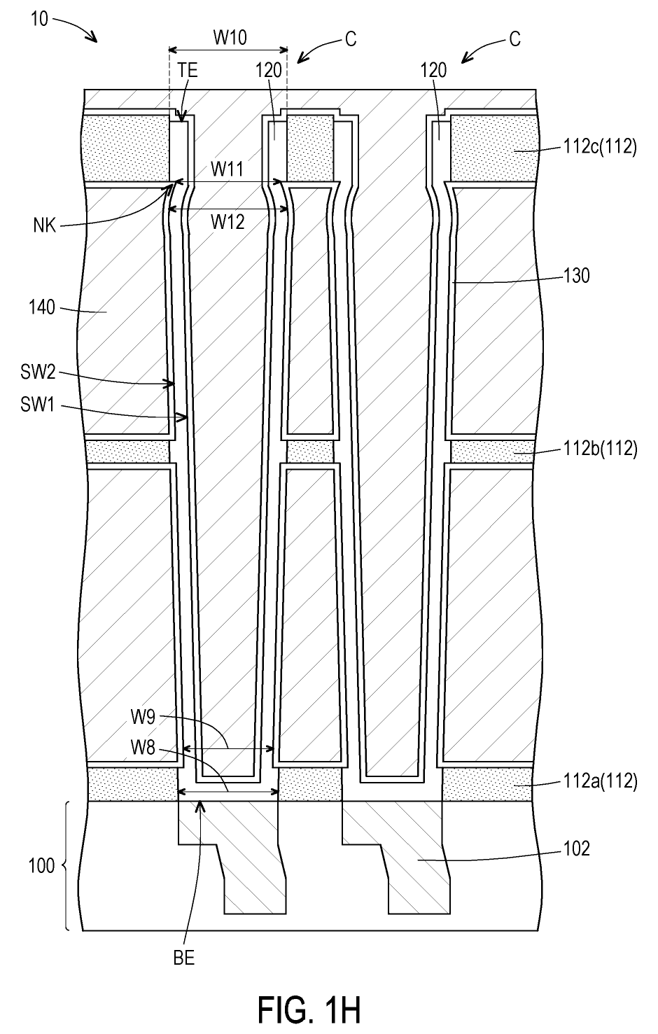

FIGS. 1A-1H are schematic cross-sectional views of the manufacturing method of a capacitor structure according to an embodiment of the present invention.

Referring to FIG. 1A, a stack structure 110 is formed over a substrate 100. For example, a first support layer 112a, a first sacrificial layer 114a, a second support layer 112b, a second sacrificial layer 114b and a third support layer 112c are sequentially formed on the substrate 100 to form the stack structure 110. Here, the first support layer 112a, the second support layer 112b and the third support layer 112c are collectively referred to support layers 112, and the first sacrificial layer 114a and the second sacrificial layer 114b are collectively referred to sacrificial layers 114. In some embodiments, the support layers 112 and the sacrificial layers 144 may be formed by chemical vapor deposition (CVD) method, physical vapor deposition (PVD) method or other suitable methods, which is not limited.

In some embodiments, a material of the support layers 112 include nitride (such as silicon nitride or the like) or other suitable materials. In some embodiments, a material of the sacrificial layers 114 include oxide (such as silicon oxide or the like) or other suitable materials.

In some embodiments, the substrate 100 includes landing pads 102 and transistors (not shown) electrically connected with the corresponding landing pads 102. In some embodiments, a material of the landing pads 102 include copper, aluminum, tungsten, gold, silver, alloy of the aforementioned materials or other suitable conductive materials. In some embodiments, the substrate 100 further includes driving circuits (such as bit lines, word line or the like) (not shown) electrically connected with the transistors.

Referring to FIG. 1B, openings OP1 are formed in the stack structure 100 to expose the landing pads 102. For example, a patterned mask (such as a hard mask layer and/or a photoresist layer)(not shown) is formed on the stack structure 100, then using the patterned mask as an etching mask, one or more etching processes are performed to remove a portion of the stack structure 110 (including the support layers 112 and the sacrificial layers 114) until the landing pads 102 are exposed and thereby the openings OP1 are formed in the stack structure 110. Then, the patterned mask is removed. Please note that FIG. 1B schematically shows two openings OP1 but the present invention is not limited thereto. The number of the opening OP1 is not limited and can be adjusted by a practical requirement.

In some embodiments, the etching process may be a dry etching process, for example, a plasma etching process. Since a plasma scattering effect may be easily occurred at an upper portion of the second sacrificial layer 114b, the upper portion of the second sacrificial layer 114b is etched more than other portions of the support layers 112 and the sacrificial layers 114. Therefore, a maximum width Wₘₐₓ of the opening OP1 is located in the upper portion of the second sacrificial layer 114b and close to the third support layer 112c.

In some embodiments, a width of the opening OP1 may gradually decrease from a position of the opening OP1 having the maximum width Wₘₐₓ to a bottom surface of the opening OP1 (that is, the exposed surface of the landing pad 102). In some embodiments, a width of the opening OP1 may gradually decrease from a position of the opening OP1 having the maximum width Wₘₐₓ to a position of the opening OP1 at an interface of the third support layer 112c and the second sacrificial layer 114b. In some embodiments, a width of the opening OP1 in the third support layer 112c is substantially the same.

In some embodiments, a top width Wₜₒₚ of the opening OP1 is in a range of 0.025 μm to 0.05 μm.

In some embodiments, the shortest distance D1 between the adjacent openings OP1 is a distance between an opening OP1 at its maximum width and adjacent opening OP1 at its maximum width. In some embodiments, the shortest distance D1 between the adjacent openings OP1 is in a range of 0.01 μm to 0.025 μm.

Referring to FIG. 1C, bottom electrodes 120 are formed in the openings OP1. For example, a conductive material layer (not shown) is first deposited on a top surface of the stack structure 110, sidewalls of the openings OP1 and a portion of the substrate 100 exposed by the openings OP1 (that is, the landing pads 102). In some embodiments, the conductive material layer is formed by chemical vapor deposition (CVD) method, physical vapor deposition (PVD) method, atomic layer deposition (ALD) method, plating process or other suitable methods. Then, a planarization process is performed until the top surface of the stack structure 110 is exposed and thereby the bottom electrodes 120 are formed, and each bottom electrodes are located in one of the openings OP1. That is to say, a portion of the conductive material layer formed on the third support layer 112c is removed during the planarization process, so the bottom electrodes 120 are physically disconnected with each other. In some embodiments, the planarization process may include a chemical mechanical polishing process, mechanical grinding process or other suitable processes. In some embodiments, the bottom electrodes 120 are conformally formed in the openings OP1, and thus the bottom electrodes 120 have cup-like shapes.

In some embodiments, a material of the conductive material layer or the bottom electrodes 120 includes titanium nitride (TiN). In some embodiments, the bottom electrode 120 is doped with silicon (Si) to increase a hardness of the bottom electrode 120 and reduce the possibility of being etched during the subsequent removal process of the sacrificial layers 114. In an embodiment that the bottom electrode 120 is doped with silicon, the bottom electrode 120 may include titanium silicon nitride (TiSiN). However, the material of the bottom electrode 120 is not limited in the present invention. In other embodiments, a material of bottom electrode 120 may include metal (such as copper (Cu), tungsten (W), gold (Au), silver (Ag), titanium (Ti), aluminum (Al) or the like) or other suitable conductive materials.

In some embodiments, a thickness of the bottom electrode 120 is substantially the same in the opening OP1. In some embodiments, a thickness T1 of an upper portion of the bottom electrode 120 may be slightly greater than a thickness T2 of a lower portion of the bottom electrode 120. Here, the thickness of the bottom electrode 120 is measured along a direction vertical to a surface that the bottom electrode 120 is in contact with.

Referring to FIG. 1D, the sacrificial layers 114 (including the first sacrificial layer 114a and the second sacrificial layer 114b) are removed by an etching process which selectively etches the sacrificial layers 114 but not or almost not etches the support layers 112 and the bottom electrodes 120, so that an inner surface S1 and an outer surface S2 of the bottom electrode 120 are exposed. The outer surface S2 is opposite to the inner surface S1 and the outer surface S2 is connected directly with the support layers 112. Also, the support layers 112 (including the first support layer 112a, the second support layer 112b and the third support layer 112c) are exposed after the removal of the sacrificial layers 114.

Referring to FIG. 1E, an oxide layer 124 is deposited on the bottom electrodes 120 by atomic layer deposition (ALD). For example, the oxide layer 124 is deposited on the exposed inner surfaces S1 and the outer surfaces S2 of the bottom electrodes 120 and also on the exposed surfaces of the support layers 112. In some embodiments, a material of the oxide layer 124 includes silicon oxide or other suitable oxide materials.

During the depositing of the oxide layer 124, a portion of the bottom electrodes 120 (for example, the exposed inner surfaces S1 and the outer surfaces S2 of the bottom electrodes 120) is oxidized to form oxide films 122. The oxide film 122 is located between the oxide layer 124 and a portion of the bottom electrode 120 which is not oxidized. In some embodiments, the oxide films 122 include titanium oxide.

In some embodiments, a thickness of the oxide film 122 is smaller than a thickness of the oxide layer 124. In some embodiments, a thickness of the oxide layer 124 is in a range of 10 nm to 20 nm and a thickness of the oxide film 122 is in a range of 5 Å to 50 Å, but it is not limited. The thickness of the oxide film 122 may be affected by the process conditions (such as process temperature, process duration and etc.) of the deposition of the oxide film 130.

Referring to FIG. 1F, the oxide layer 124 and the oxide films 122 of the bottom electrodes 120 are removed to modify the profile of the bottom electrodes 120. For example, the oxide layer 124 and the oxide films 122 may be removed by a wet etching process. An etchant used in the wet etching process may be diluted hydrofluoric acid (DHF) or other suitable etchants.

Since portions of the inner surface S1 and outer surface S2 of the bottom electrode 120 are oxidized, after removing the oxide layer 124 and the oxide films 122, a thickness of the bottom electrode 120 is reduced. In some embodiments, an average thickness of the remaining bottom electrode 120 after the oxide layer 124 and the oxide films 122 are removed is less than an average thickness of the bottom electrode 120 before the oxide layer 124 is deposited.

In some embodiments, the shortest distance D2 between the adjacent bottom electrodes 120 is a distance between the widest part of the adjacent bottom electrodes 120, and the widest part of the bottom electrode 120 is located in the upper portion of the bottom electrode 120 and close to the third support layer 112c.

In some embodiments, the shortest distance D2 between the adjacent bottom electrodes 120 is larger than the shortest distance D1 between the adjacent openings OP1 (shown in FIG. 1B). Since the profile of the bottom electrodes 120 are modified, the shortest distance D2 between the adjacent bottom electrodes 120 is increased and thereby the possibility of short circuit between the adjacent capacitors subsequently formed is reduced. The shortest distance D2 between the adjacent bottom electrodes 120 may be the critical dimension of the embodiment. In some embodiments, the shortest distance D2 between the adjacent bottom electrodes 120 is in a range of 0.012 μm to 0.030 μm and is located close to the third support layer 112c.

In some embodiments, a thickness of a portion of a bottom electrode 120 in direct contact with a support layer 112 is greater than a thickness of a portion of the bottom electrode 120 adjacent to the support layer 112 but not in contact with the support layer 112. For example, a thickness T3 of a portion of a bottom electrode 120 in direct contact with the second support layer 112b is greater than a thickness T4 of a portion of the bottom electrode 120 adjacent to an upper surface of the second support layer 112b but not in contact with the second support layer 112b. Also, the thickness T3 of a portion of a bottom electrode 120 in direct contact with the second support layer 112b is greater than a thickness T5 of a portion of the bottom electrode 120 adjacent to a lower surface of the second support layer 112b but not in contact with the second support layer 112b. Similarly, a thickness T6 of a portion of a bottom electrode 120 in direct contact with the third support layer 112c is greater than a thickness T7 of a portion of the bottom electrode 120 adjacent to the third support layer 112c but not in contact with the third support layer 112c. A thickness T8 of a portion of a bottom electrode 120 in direct contact with the first support layer 112a is greater than a thickness T9 of a portion of the bottom electrode 120 adjacent to the first support layer 112a but not in contact with the first support layer 112a.

In some embodiments, a width of a portion of a bottom electrode 120 in direct contact with a support layer 112 is greater than a width of a portion of the bottom electrode 120 adjacent to the support layer 112 but not in contact with the support layer 112. In an embodiment where the bottom electrode 120 has a cup-like shape, a width of the bottom electrode 120 at a certain location may refer to an outer diameter of the bottom electrode 120 at the certain location.

For example, a width W1 (also called a first width W1) of a portion of a bottom electrode 120 in direct contact with the second support layer 112b is greater than a width W2 (also called a second width W2) of a portion of the bottom electrode 120 adjacent to an upper surface of the second support layer 112b but not in contact with the second support layer 112b. Also, the width W1 of a portion of a bottom electrode 120 in direct contact with the second support layer 112b is greater than a width W3 (also called a third width W3) of a portion of the bottom electrode 120 adjacent to a lower surface of the second support layer 112b but not in contact with the second support layer 112b. Similarly, a width W4 of a portion of a bottom electrode 120 in direct contact with the third support layer 112c is greater than a width W5 of a portion of the bottom electrode 120 adjacent to the third support layer 112c but not in contact with the third support layer 112c, and a width W6 of a portion of a bottom electrode 120 in direct contact with the first support layer 112a is greater than a width W7 of a portion of the bottom electrode 120 adjacent to the first support layer 112a but not in contact with the first support layer 112a.

Referring to FIG. 1G, an insulation layer 130 is formed on the bottom electrodes 120. For example, the insulation layer 130 is formed by ALD method or other suitable methods. In some embodiments, the insulation layer 130 is conformally formed over the substrate 100, so that the insulation layer 130 is disposed on the exposed surfaces of the bottom electrode 120 (such as the inner surface S1 and the outer surface S2) and the exposed surfaces of the support layers 112.

In some embodiments, the insulation layer 130 includes a high-k dielectric material whose dielectric constant is greater than or equal to the dielectric constant of silicon oxide. For example, a material of the insulation layer 130 includes hafnium oxide, aluminum oxide, zirconium oxide, silicon oxide, lanthanum oxide, magnesium oxide or other suitable high-k materials.

Referring to FIG. 1H, a top electrode 140 is formed on the insulation layer 130. For example, the top electrode 140 is formed by ALD method or other suitable methods. In some embodiments, the top electrode 140 is conformally formed over the substrate 100, so that the top electrode 140 extends along a surface of the insulation layer 130. In some embodiments, the top electrode 140 may fill the remaining space released by the sacrificial layers 114 and the openings OP1.

In some embodiments, a material of the top electrode 140 includes titanium nitride (TiN). However, the material of the top electrode 140 is not limited in the present invention. In other embodiments, a material of top electrode 140 may include metal (such as copper (Cu), tungsten (W), gold (Au), silver (Ag), titanium (Ti), aluminum (Al) or the like) or other suitable conductive materials.

Based on the above, the forming of a capacitor structure 10 is substantially completed.

Referring to FIG. 1H, the capacitor structure 10 includes a plurality of capacitors C. Each capacitors C includes a bottom electrode 120, an insulation layer 130 disposed on the bottom electrode 120 and a top electrode 140 disposed on the insulation layer 130. In some embodiments, the capacitor structure 10 further includes support layers 112 connected with the bottom electrodes 120 of the capacitors C. In some embodiments, a width of a portion of a bottom electrode 120 in direct contact with a support layer 112 is greater than a width of a portion of the bottom electrode 120 adjacent to the support layer 112 but not in contact with the support layer 112. Please note that FIG. 1H schematically shows two capacitors C but the present invention is not limited thereto. The number of the capacitor C is not limited and can be adjusted by a practical requirement.

In some embodiments, the insulation layer 130 is disposed on the inner surfaces S1 (labeled in FIG. 1G), outer surfaces S2 (labeled in FIG. 1G) and top ends TE of the bottom electrodes 120 and extends on to the surfaces of the support layers 112. In some embodiments, the insulation layers 130 of each capacitor C are connected to each other, and the top electrodes 140 of each capacitor C are connected to each other. The bottom electrodes 120 of each capacitor C are separated.

In some embodiments, the bottom electrodes 120 of the capacitors C are spaced apart from each other by at least a distance in a range of 0.012 μm to 0.030 μm. In some embodiments, a top width W10 of the bottom electrode 120 of the capacitor C is in a range of 0.025 μm to 0.05 μm. In this way, the capacitance structure 10 may have multiple capacitors C having large contact surface to obtain large capacitance, and the critical dimension of the adjacent capacitors C is increased within a limited space to reduce the possibility of short circuit problem occurred between two adjacent capacitors C.

In some embodiments, the bottom electrode 120 has a cup-like shape, but it is not limited. In other embodiments, the bottom electrode 120 may have a pillar-like shape or other suitable shape. In some embodiments, the bottom electrode 120 has a maximum width at an upper portion of the bottom electrode 120 and adjacent to a bottom surface of the third support layer 112c.

In some embodiments, a thickness of a portion of a bottom electrode 120 in direct contact with a support layer 112 is greater than a thickness of a portion of the bottom electrode 120 adjacent to the support layer 112 but not in contact with the support layer 112. From another point of view, the outer sidewall SW2 of the bottom electrode 120 is protruded toward the support layers 112 to have a step change and the inner sidewall SW1 of the bottom electrode 120 has substantially a smooth surface.

In some embodiments, the support layers 112 includes a first support layer 112a, a second support layer 112b and the third support layer 112c. The first support layer 112a surrounds the bottom end BE of the bottom electrode 120. The third support layer 112c surrounds a top end TE of the bottom electrode 120. The second support layer 112b is located between the first support layer 112a and the third support layer 112c and surrounds a portion of the bottom electrode 120 between the top end TE and the bottom end BE.

In some embodiments, a width W8 of a lower portion of the bottom electrode 120 in direct contact with the first support layer 112a is greater than a width W9 of the lower portion of the bottom electrode 120 adjacent to the first support layer 112a but not in contact with the first support layer 112a.

In some embodiments, a neck NK of the bottom electrode 120 is located adjacent to a bottom surface of the third support layer 112c. A width W11 of the bottom electrode 120 at the neck NK is smaller than a width W10 of the bottom electrode 120 at the top end TE of the bottom electrode 120 and is smaller than a width W12 of the bottom electrode 120 below the neck NK and adjacent to the third support layer 112c.

In some embodiments, the capacitor structure 10 is disposed on a substrate 100 and electrically connected with the substrate 100. In some embodiments, the substrate 100 includes landing pads 102 and transistors (not shown) electrically connected with the corresponding landing pads 102. Each capacitor C is electrically connected to the corresponding landing pad 102. In some embodiments, the capacitor structure 10 may be electrically connected to the corresponding transistors through the corresponding landing pads 102 to form memory cells, such as DRAM cells or the like.

In the present embodiment, the capacitance structure 10 includes multiple capacitors C to have high capacitance and the critical dimension of the capacitance structure 10 is increased within a limited space to reduce the possibility of short circuit problem occurred between two adjacent capacitors C.

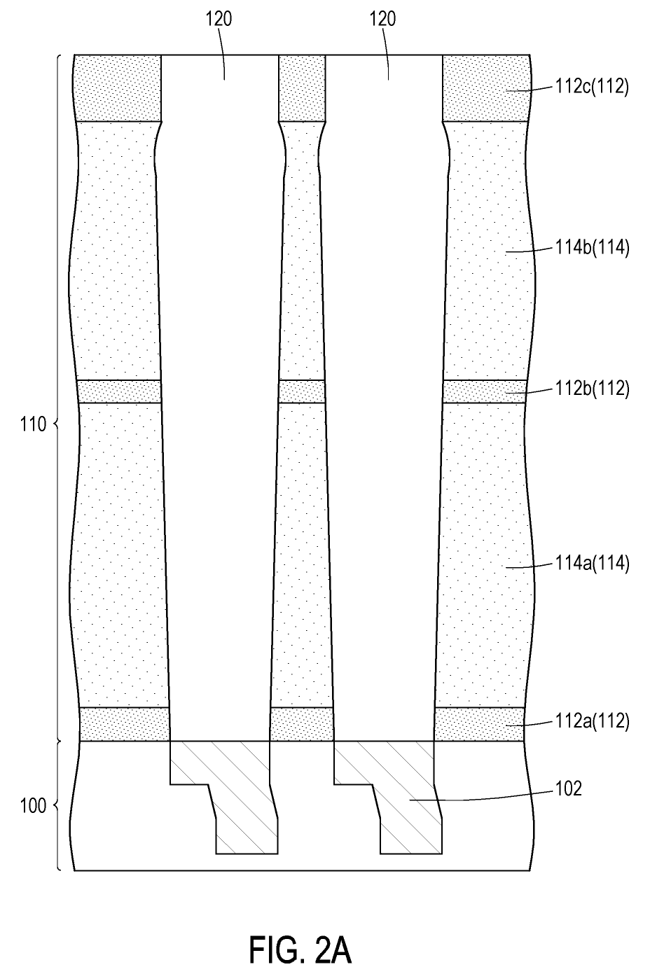

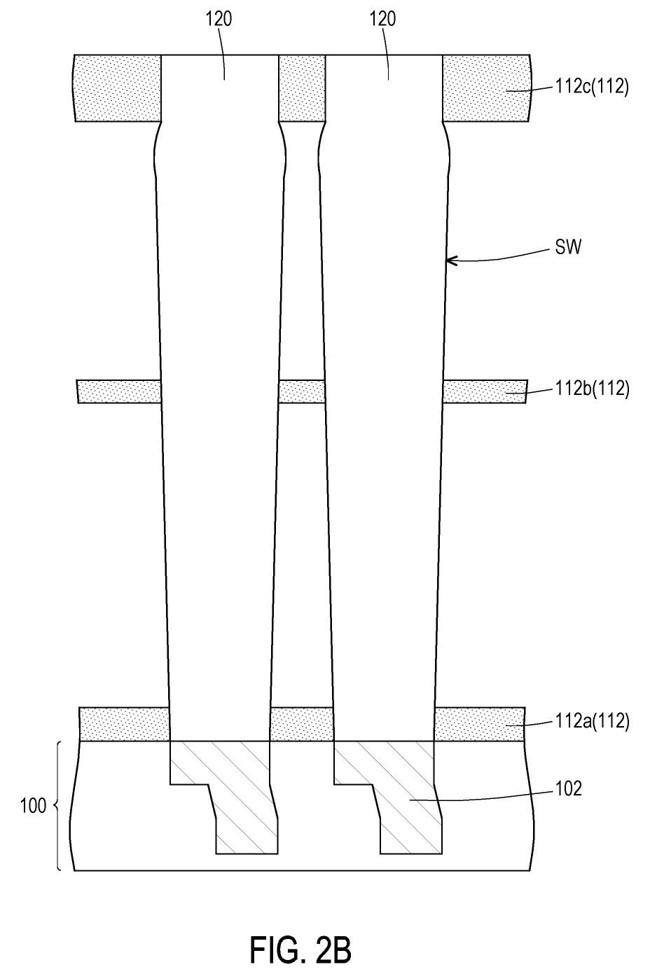

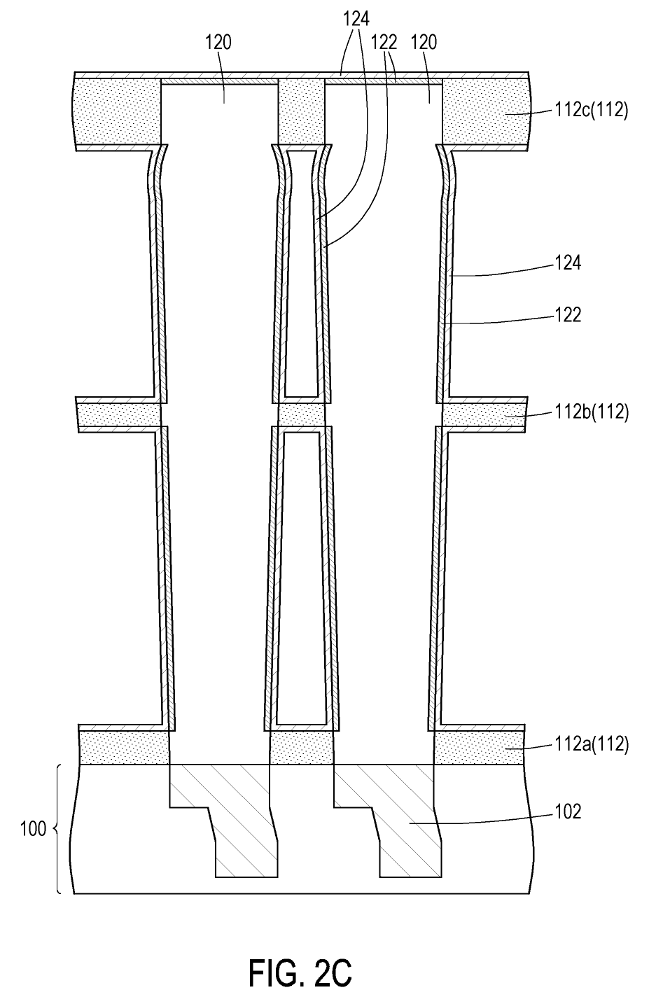

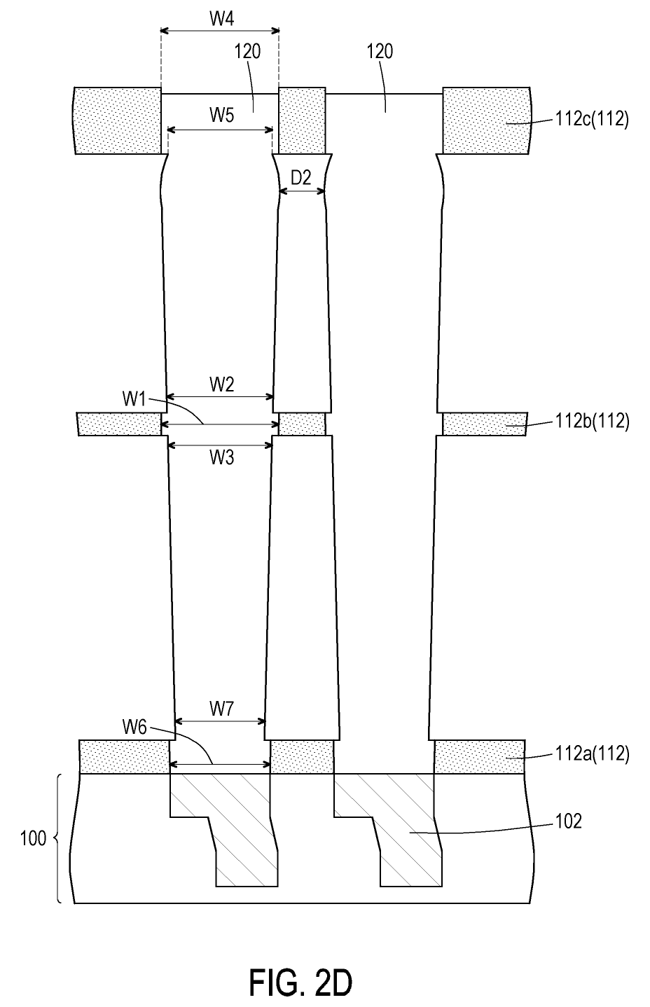

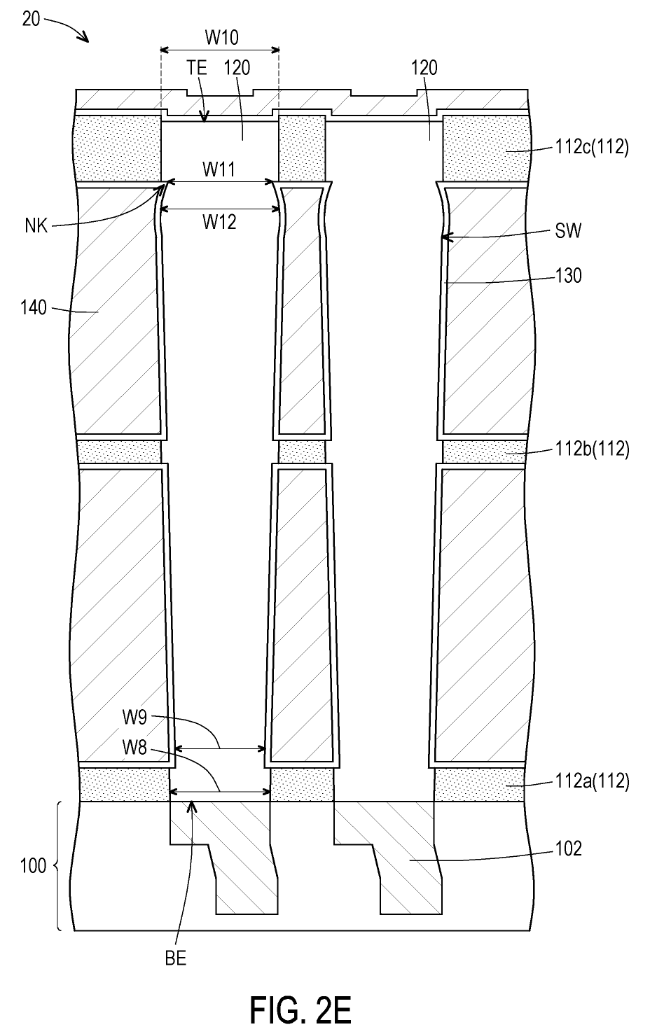

FIGS. 2A-2E are schematic cross-sectional views of the manufacturing method of a capacitor structure according to another embodiment of the present invention. It must be noted here that the embodiment in FIGS. 2A-2E continues to use the referential numbers of the elements and a part of the contents of the embodiments of FIGS. 1A-1H, wherein the same or similar referential numbers are used to denote the same or similar elements, and the description of the same technical contents is omitted. For the description of the omitted part, reference may be made to the foregoing embodiments, and details are not repeated here. FIGS. 2A-2E may be a continuation process of FIG. 1B.

Referring to FIG. 2A continuing from the process of FIG. 1B, bottom electrodes 120 are formed in the openings OP1. For example, a conductive material layer (not shown) is first deposited on a top surface of the stack structure 110 and fills in the openings OP1. In some embodiments, the conductive material layer is formed by chemical vapor deposition (CVD) method, physical vapor deposition (PVD) method, atomic layer deposition (ALD) method, plating process or other suitable methods. Then, a planarization process is performed until the top surface of the stack structure 110 is exposed and thereby the bottom electrodes 120 are formed, and each bottom electrodes 120 are located in one of the openings OP1. That is to say, a portion of the conductive material layer formed on the third support layer 112c is removed during the planarization process, so the bottom electrodes 120 are physically disconnected with each other. In some embodiments, the planarization process may include a chemical mechanical polishing process, mechanical grinding process or other suitable processes. In this embodiments, the bottom electrodes 120 are filled in the openings OP1 to form pillar-like shapes.

Referring to FIG. 2B, the sacrificial layers 114 (including the first sacrificial layer 114a and the second sacrificial layer 114b) are removed to expose sidewalls SW of the bottom electrodes 120, similar to the process described in FIG. 1D.

Referring to FIG. 2C, an oxide layer 124 is deposited on the bottom electrodes 120 by atomic layer deposition (ALD). For example, the oxide layer 124 is deposited on the exposed sidewalls SW of the bottom electrodes 120 and also on the exposed surfaces of the support layers 112. During the depositing of the oxide layer 124, a portion of the bottom electrodes 120 (for example, the exposed sidewalls SW of the bottom electrodes 120) is oxidized to form oxide films 122, similar to the process described in FIG. 1E.

Referring to FIG. 2D, the oxide layer 124 and the oxide films 122 of the bottom electrodes 120 are removed to modify the profile of the bottom electrodes 120, similar to the process described in FIG. 1F. Since a portion of the sidewall SW of the bottom electrode 120 is oxidized, after removing the oxide layer 124 and the oxide films 122, a width of the bottom electrode 120 is reduced. In some embodiments, an average width of the remaining bottom electrode 120 after the oxide layer 124 and the oxide films 122 are removed is less than an average width of the bottom electrode 120 before the oxide layer 124 is deposited.

Referring to FIG. 2E, an insulation layer 130 is formed on the bottom electrodes 120, and then a top electrode 140 is formed on the insulation layer 130, which is similar to the process described in FIGS. 1G and 1H.

Based on the above, the forming of a capacitor structure 20 is substantially completed.

Referring to FIG. 2E, the main difference between a capacitor structure 20 of the embodiment and the capacitor structure 10 is that each bottom electrode 120 of the capacitor structure 20 has a pillar-like shape, for example a cylinder-like shape, a taper-like shape or the like. The insulation layer 130 is disposed on the sidewalls SW and top ends TE of the bottom electrodes 120 and extends on to the surfaces of the support layers 112.

In some embodiments, the sidewall SW of the bottom electrode 120 is protruded toward the support layers 112 to have a step change. A width of a portion of a bottom electrode 120 in direct contact with a support layer 112 is greater than a width of a portion of the bottom electrode 120 adjacent to the support layer 112 but not in contact with the support layer 112.

Since the surface of the bottom electrode 120 is modified, the critical dimension of the capacitance structure 20 is increased within a limited space to reduce the possibility of short circuit problem occurred between two adjacent capacitors C.

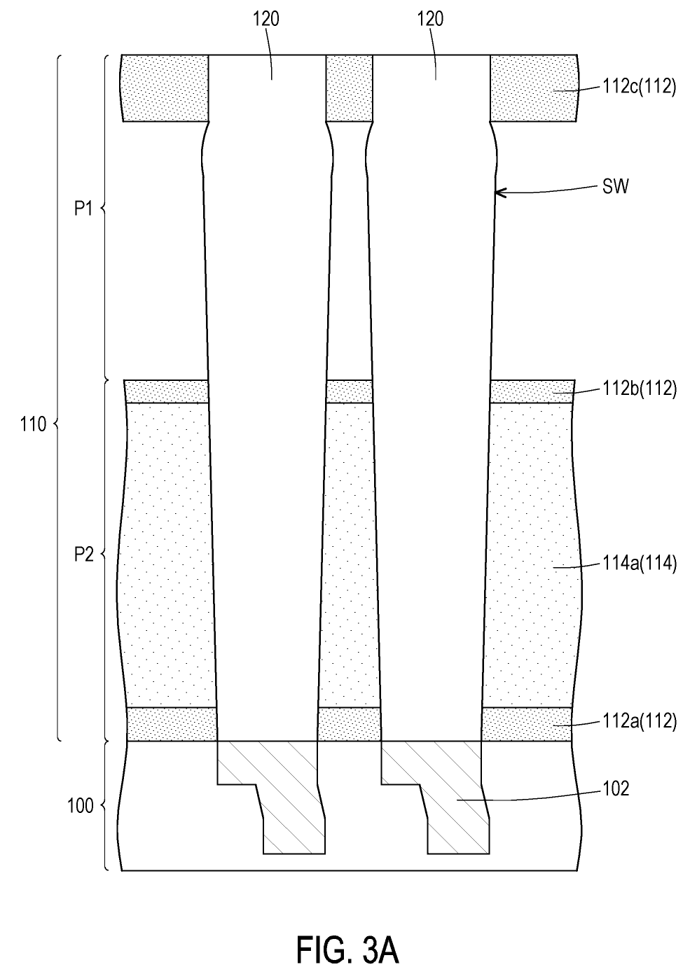

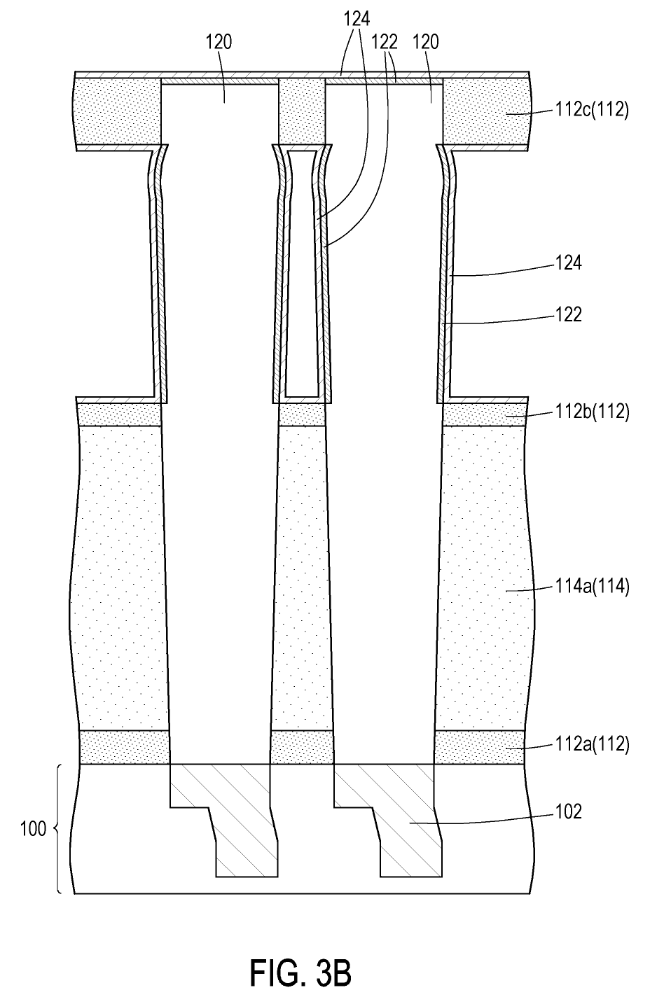

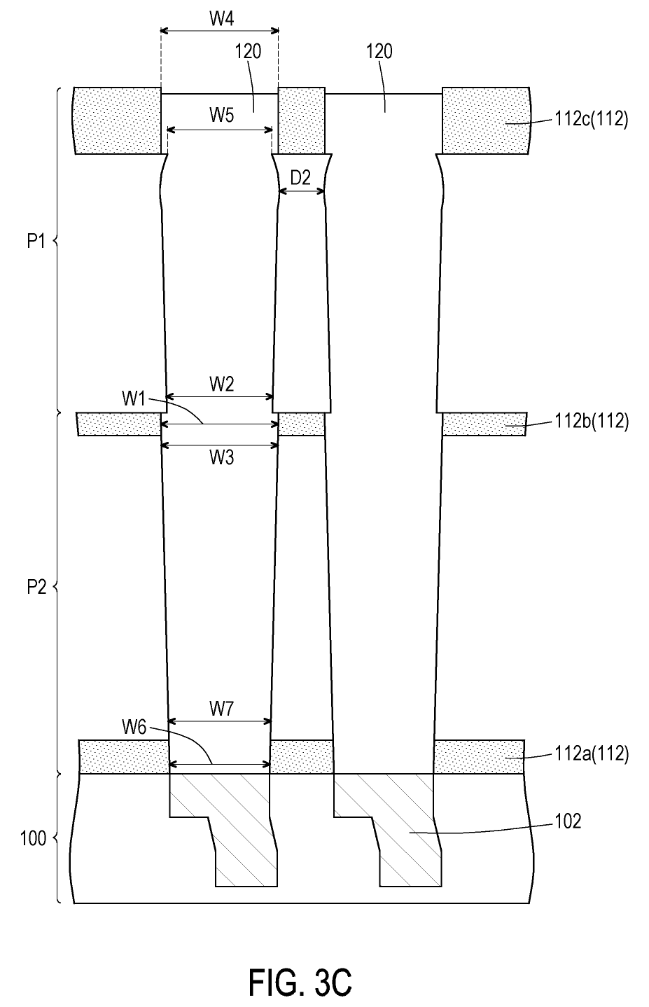

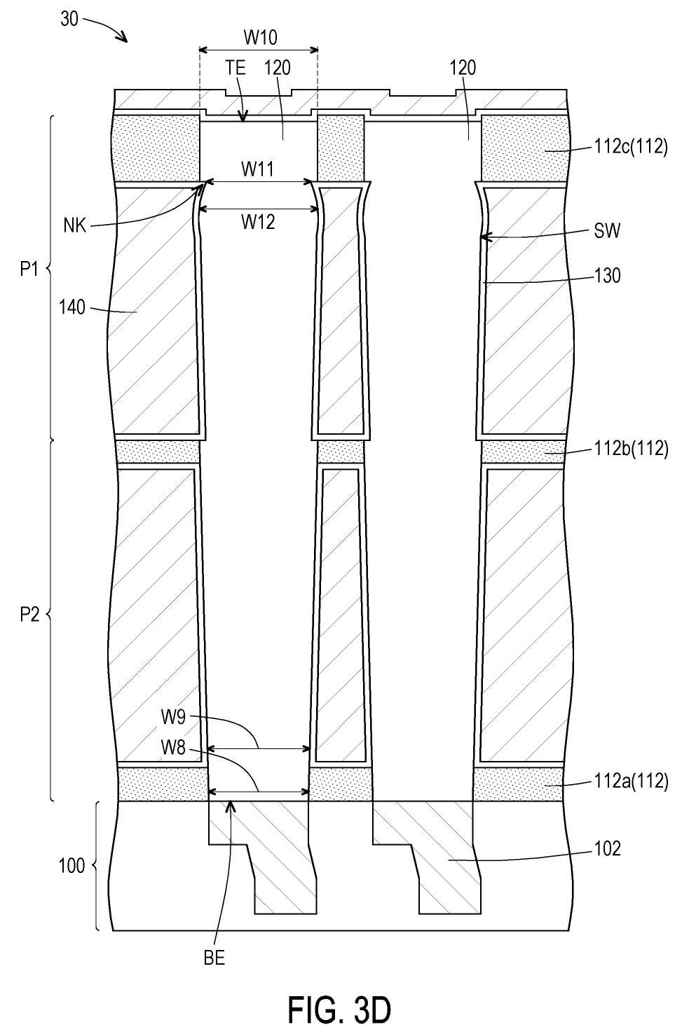

FIGS. 3A-3D are schematic cross-sectional views of the manufacturing method of a capacitor structure according to another embodiment of the present invention. It must be noted here that the embodiment in FIGS. 3A-3D continues to use the referential numbers of the elements and a part of the contents of the embodiments of FIGS. 1A-1H and 2A-2E, wherein the same or similar referential numbers are used to denote the same or similar elements, and the description of the same technical contents is omitted. For the description of the omitted part, reference may be made to the foregoing embodiments, and details are not repeated here. FIGS. 3A-3D may be a continuation process of FIG. 2A.

Referring to FIG. 3A continuing from the process of FIG. 2A, the second sacrificial layer 114b is removed to expose a portion of sidewalls SW of the bottom electrodes 120. Specifically, the sidewalls SW of an upper portion P1 of the bottom electrodes 120 are exposed, and the sidewalls SW of a lower portion P2 of the bottom electrodes 120 is still covered by the second support layer 112b, the first sacrificial layer 114a and the first support layer 112a. In some embodiments, a bottom surface of the third support layer 112c and a top surface of the second support layer 112b are also exposed after the removal of the second sacrificial layer 114b.

Referring to FIG. 3B, an oxide layer 124 is deposited on the bottom electrodes 120 by atomic layer deposition (ALD). For example, the oxide layer 124 is deposited on the exposed sidewalls SW of the bottom electrodes 120 and also on the exposed surfaces of the support layers 112. During the depositing of the oxide layer 124, a portion of the bottom electrodes 120 (for example, the exposed sidewalls SW of the bottom electrodes 120) is oxidized to form oxide films 122. The portion of the sidewalls SW of the bottom electrodes 120 covered by the second support layer 112b, the first sacrificial layer 114a and the first support layer 112a is not oxidized.

Referring to FIG. 3C, the oxide layer 124 and the oxide films 122 of the bottom electrodes 120 are removed to modify the profile of the upper portion P1 of the bottom electrodes 120, and the first sacrificial layer 114a is removed. In some embodiments, the oxide layer 124, the oxide films 122 and the first sacrificial layer 114a are removed in the same etching step, but it is not limited. In other embodiments, the first sacrificial layer 114a is removed in a different etching step from the step of removal of the oxide layer 124 and the oxide films 122.

Since the sidewall SW of the upper portion P1 of the bottom electrode 120 is oxidized, after removing the oxide layer 124 and the oxide films 122, a thickness of the upper portion P1 of the bottom electrode 120 is reduced. In some embodiments, an average thickness of the upper portion P1 of the remaining bottom electrode 120 after the oxide layer 124 and the oxide films 122 are removed is less than an average thickness of the upper portion P1 of the bottom electrode 120 before the oxide layer 124 is deposited. Since the sidewall SW of the lower portion P2 of the bottom electrode 120 is not oxidized, the thickness of the lower portion P2 of the bottom electrode 120 substantially remains the same after the oxide layer 124 and the oxide films 122 are removed.

Since the surface of the upper portion P1 of the bottom electrode 120 is modified, a width W1 of a portion of a bottom electrode 120 in direct contact with the second support layer 112b is greater than a width W2 of a portion of the bottom electrode 120 adjacent to an upper surface of the second support layer 112b but not in contact with the second support layer 112b and a width W4 of a portion of a bottom electrode 120 in direct contact with the third support layer 112c is greater than a width W5 of a portion of the bottom electrode 120 adjacent to the third support layer 112c but not in contact with the third support layer 112c.

Since the surface of the lower portion P2 of the lower electrode 120 is not modified, the width W1 of a portion of a bottom electrode 120 in direct contact with the second support layer 112b is greater than a width W3 of a portion of the bottom electrode 120 adjacent to a lower surface of the second support layer 112b but not in contact with the second support layer 112b, and a width W6 of a portion of a bottom electrode 120 in direct contact with the first support layer 112a is smaller than a width W7 of a portion of the bottom electrode 120 adjacent to the first support layer 112a but not in contact with the first support layer 112a.

In some embodiments, a width of the lower portion P2 of the bottom electrode 120 gradually decreases from the second support layer 112b to the first support layer 112a.

Referring to FIG. 3D, an insulation layer 130 is formed on the bottom electrodes 120, and then a top electrode 140 is formed on the insulation layer 130, which is similar to the process described in FIGS. 1G and 1H.

Based on the above, the forming of a capacitor structure 30 is substantially completed.

Referring to FIG. 3D, the main difference between a capacitor structure 30 of the embodiment and the capacitor structure 20 is that a width of the lower portion P2 of the bottom electrode 120 gradually decreases from the second support layer 112b to the first support layer 112a. That is, a width W8 of a lower portion P2 of the bottom electrode 120 in direct contact with the first support layer 112a is smaller than a width W9 of the lower portion P2 of the bottom electrode 120 adjacent to the first support layer 112a but not in contact with the first support layer 112a.

Since the surface of upper portion P1 of the bottom electrode 120 is modified, the critical dimension of the capacitance structure 20 is increased within a limited space to reduce the possibility of short circuit problem occurred between two adjacent capacitors C.

Based on the above, the capacitance structure of the present invention includes multiple capacitors to have high capacitance and the shortest distance between the bottom electrodes of the adjacent capacitors is increased within a limited space in a simple way to reduce the possibility of short circuit problem occurred between two adjacent capacitors.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a capacitor structure, comprising:
forming a bottom electrode;
depositing an oxide layer on the bottom electrode, wherein during the depositing of the oxide layer, a portion of the bottom electrode is oxidized to form an oxide film;
removing the oxide layer and the oxide film of the bottom electrode;
forming an insulation layer on the remaining bottom electrode;
forming a top electrode on the insulation layer.

2. The manufacturing method of claim 1, wherein an average thickness of the remaining bottom electrode after the oxide layer and the oxide film are removed is less than an average thickness of the bottom electrode before the oxide layer is deposited.

3. The manufacturing method of claim 1, wherein forming the bottom electrode comprises:
forming a stack structure over a substrate, wherein the stack structure comprises a first support layer, a first sacrificial layer, a second support layer, a second sacrificial layer and a third support layer stacked sequentially over the substrate;
forming an opening penetrating through the stack structure; and
depositing the bottom electrode in the opening.

4. The manufacturing method of claim 3, further comprising:
removing the first sacrificial layer and the second sacrificial layer to expose an inner surface and an outer surface of the bottom electrode;
depositing the oxide layer on the inner surface and the outer surface of the bottom electrode, wherein during the depositing of the oxide layer, the inner surface and the outer surface of the bottom electrode is oxidized to form the oxide film.

5. The manufacturing method of claim 3, further comprising:
removing the second sacrificial layer to expose an upper portion of the bottom electrode;
depositing the oxide layer on a sidewall of the upper portion of the bottom electrode; and
removing the first sacrificial layer, the oxide layer and the oxide film of the bottom electrode.

6. The manufacturing method of claim 5, wherein during the depositing of the oxide layer, a lower portion of the bottom electrode layer is not oxidized.

7. The manufacturing method of claim 1, wherein the oxide layer comprises silicon oxide and the oxide film of the bottom electrode comprises titanium oxide.

8. A capacitor structure, comprising:
a bottom electrode;
an insulation layer disposed on the bottom electrode;
a top electrode disposed on the insulation layer; and
support layers surrounding the bottom electrode,
wherein a width of a portion of the bottom electrode in direct contact with the support layers is greater than a width of a portion of the bottom electrode adjacent to the support layers but not in contact with the support layers.

9. The capacitor structure of claim 8, wherein the support layers comprises:
a first support layer surrounding the bottom end of the bottom electrode;
a third support layer surrounding a top end of the bottom electrode; and
a second support layer located between the first support layer and the third support layer and surrounding a portion of the bottom electrode between the top end and the bottom end.

10. The capacitor structure of claim 9, wherein a first width of a portion of the bottom electrode in direct contact with the second support layer is greater than a second width of a portion of the bottom electrode adjacent to an upper surface of the second support layer but not in contact with the second support layer, and the first width of a portion of the bottom electrode in direct contact with the second support layer is greater than a third width of a portion of the bottom electrode adjacent to a lower surface of the second support layer but not in contact with the second support layer.

11. The capacitor structure of claim 9, wherein a width of a portion of the bottom electrode in direct contact with the first support layer is greater than a width of a portion of the bottom electrode adjacent to an upper surface of the first support layer but not in contact with the first support layer.

12. The capacitor structure of claim 9, wherein a neck of the bottom electrode is located adjacent to a bottom surface of the third support layer.
